(19) United States
(12) Patent Application Publication
(10) Pub. No.: US 2024/0234126 A1
(43) Pub. Date: Jul. 11, 2024

(54) METHOD FOR PREPARING A MICROELECTRONIC COMPONENT COMPRISING A LAYER WITH A BASIS OF A III-V MATERIAL

(71) Applicants: COMMISSARIAT A L'ENERGIE ATOMIQUE ET AUX ENERGIES ALTERNATIVES, Paris (FR); CENTRE NATIONAL DE LA RECHERCHE SCIENTIFIQUE, Paris (FR); UNIVERSITE GRENOBLE ALPES, Saint Martin D'Heres (FR)

(72) Inventors: Bassem SALEM, Grenoble Cedex 09 (FR); Laura VAUCHE, Grenoble Cedex 09 (FR); Maxime LEGALLAIS, Grenoble Cedex 09 (FR); Thierry BARON, Grenoble Cedex 09 (FR); Romain GWOZIECKI, Grenoble Cedex 09 (FR); Marc PLISSONNIER, Grenoble Cedex 09 (FR)

(73) Assignees: COMMISSARIAT A L'ENERGIE ATOMIQUE ET AUX ENERGIES ALTERNATIVES, Paris (FR); CENTRE NATIONAL DE LA RECHERCHE SCIENTIFIQUE, Paris (FR); UNIVERSITE GRENOBLE ALPES, Saint Martin D'Heres (FR)

(21) Appl. No.: 18/560,988

(22) PCT Filed: May 19, 2022
(86) PCT No.: PCT/EP2022/063540

§ 371 Date: Nov. 15, 2023

(30) Foreign Application Priority Data
May 20, 2021 (FR) FR2105307

(51) Int. Cl. H01L 21/02; H01L 33/00

(52) U.S. Cl. CPC H01L 21/02057; H01L 21/0254; H01L 33/0075

(57) ABSTRACT

A method for preparing a microelectronic component includes cleaning of the surface of an exposed layer with a basis of a III-V material by a cyclic plasma treatment, each cycle comprising a purge phase and a plasma treatment phase. During the formation of the plasma, a bias voltage is applied to the substrate. The method further includes depositing, on the cleaned surface, a subsequent layer. The method provides an optimal cleaning of the exposed layer while minimising, and preferably avoiding degradation of the structure. The preparation method thus makes it possible to improve the quality of the interface between the layer with a basis of a III-V material and the subsequent layer. The electrical properties of the component are consequently improved.

### TECHNICAL FIELD OF THE INVENTION

The present invention relates to the preparation of a microelectronic component comprising the cleaning of the layer with a basis of a III-V material. It has, for example, an advantageous application in the field of microelectronics, and more specifically, the fields of power electronics, sensors and optoelectronics.

### PRIOR ART

The properties of III-V semi-conductive materials make these materials particularly attractive for numerous applications in the field of sensors, optoelectronic components, and also power electronics. These materials are generally used in multilayer stacks, at the interface with other materials, such as dielectrics. The quality of these interfaces is determining in the correct operation of the microelectronic components comprising these stacks.

For example, light-emitting diodes (LEDs) can comprise one or more gallium nitride (GaN)-based and/or indium-gallium nitride (InGaN)-based layers. The defects at the interface of these layers induce recombination phenomena, degrading the operation of the LEDs.

According to another example, in GaN- and/or AlGaN-based high-electron-mobility transistors (HEMTs), the defects at the interface between the semiconductor and the insulator highly degrade the electric performance of the components. In particular, this poor interface quality is conveyed by instabilities and by an offsetting of the threshold voltage to negative values. Yet, for certain applications, for safety conditions, it is preferable that these transistors display a positive threshold voltage, “normally-off” HEMT transistors are thus referred to.

Thus, for these types of applications linked to HEMTs or to LEDs, but also for numerous other applications, there is a general need consisting of proposing a solution making it possible to improve the quality of the III-V material layer interfaces, for example, between a layer of a III-V material and another layer of a III-V material, or between a layer of a III-V material and a layer of a dielectric material.

In order to improve the quality of the III-V material-based layer interfaces, wet and/or dry preparation methods are generally used.

In literature, surface treatments of an exposed III-N material layer are described, generally done in-situ just before the deposition of the gate dielectric for the HEMT preparation. These treatments aim to remove and/or repair the surface of the exposed layer. The effectiveness of these nitrogen-based plasma treatments has been demonstrated for the surface preparation of the III-V materials before the deposition of the gate dielectric. The electric performance of HEMTs which result from these is thus clearly improved, such as the slope under the threshold, the On/Off current ratio and the threshold voltage.

Despite the existence of these known plasma treatment techniques, there remains a need consisting of proposing a solution making it possible to improve the quality of the III-V material layer interfaces, and more specifically, III-N materials.

An aim of the present invention is therefore to propose a solution to improve the interface between a III-V-type material layer, more specifically of the III-N type, and a layer deposited consecutively.

Other aims, features and advantages of the present invention will appear upon examining the following description and the accompanying drawings. It is understood that other advantages can be incorporated.

### SUMMARY OF THE INVENTION

To achieve this aim, according to a first aspect, a method for preparing a microelectronic component is provided, comprising:
a provision of a structure comprising an exposed layer with a basis of a III-V material and having a surface, in a plasma reactor comprising a reaction chamber inside which a substrate comprising said structure is disposed,
a cleaning of the surface of the exposed surface by a cyclic plasma treatment comprising several treatment cycles, each treatment cycle comprising at least:
   a purge of the reaction chamber,
   an injection of at least one gas into the reaction chamber and a formation of a plasma from said gas in the reaction chamber, during which a bias voltage V_{bias-substrate} is applied to the substrate,
a deposition, on the cleaned surface, of a second layer of a material with a basis of at least one chemical element chosen from among an element of column III and an element of column V of the periodic table and/or with a basis of a metal oxide.

For a layer with the basis of a III-V or III-N material, at the interface with a layer with the basis of a III-V material and/or with the basis of a metal oxide, the structural defects at the layer interfaces, such as dislocations, implantation of elements, dangling bonds or gaps, as well as surface contamination, such as the oxidation of III-V and III-N materials or carbon contamination will degrade the properties of the microelectronic component obtained. During the development of the invention, it has been observed that a cyclic plasma treatment enables a considerably improved cleaning of the surface of the exposed layer, while minimising, and preferably avoiding, a possible degradation of the structure, as can be observed for existing cleaning solutions, in particular those implementing a continuous plasma.

The exposed layer is thus particularly capable of receiving the deposition of a second layer, to form a good quality interface. The preparation method thus makes it possible to improve the quality of the interface between the layer with the basis of a III-V material and the subsequent layer, with respect to existing solutions.

The application of a bias voltage to the substrate makes it possible to increase the energy of the ions of the plasma accurately, in a controlled manner, and independently from the potential of the plasma Vₚₗₐₛₘₐ. In practice, it has indeed proved to be that controlling the energy of the ions by the plasma source is limited and barely reliable. The effectiveness of the cyclic plasma treatment can thus be modulated accurately and in a controlled manner to also improve the properties of the interface obtained. The electric performance of the component is consequently improved.

For the preparation of a transistor, the active layer of which is with the basis of a III-V material, the method avoids, in particular, offsetting the threshold voltage to negative voltages, and improves the slope under the threshold. The method is thus particularly advantageous for preparing transistors, in particular power transistors, having good electrical properties, and in particular, for HEMT-type transistors.

For the preparation of an LED, by improving the quality of the interfaces, the method enables a decrease of the interface states, these being able to induce interfering recombinations decreasing the light emission effectiveness of the LEDs.

A second aspect relates to a microelectronic component obtained by the method according to the first aspect. According to an example, the component is an LED. According to another example, the component is a transistor, an active layer of which is the layer with the basis of a cleaned III-V material, preferably the microelectronic component is a power transistor, and preferably an HEMT-type transistor.

### BRIEF DESCRIPTION OF THE FIGURES

The aims, objectives, as well as the features and advantages of the invention will best emerge from the detailed description of an embodiment of the latter, which is illustrated by the following accompanying drawings, wherein:

FIG. 1 schematically represents a cyclic plasma treatment cycle according to an example of an embodiment of the invention.

FIG. 2 schematically represents an example of a deposition reactor which could be used to implement the method according to the invention.

FIG. 3 represents a cross-sectional view of an example of a metal-insulator-semiconductor-type capacitive electronic component obtained by the method according to 20 the invention.

FIGS. 4A and 4B represent a graph of the electrical features of the electronic component illustrated in FIG. 3, after treatment by an in-situ N₂—H₂ plasma, respectively cyclic and continuous on the surface of the GaN-based layer.

FIG. 5 represents a graph of the development of the parameters extracted from FIGS. 4A and 4B, according to a cyclic or content plasma treatment, these parameters being (A): the voltage V₃ of the forward stroke curve extracted at a capacity of 8×10⁻¹⁰ F; (B) the hysteresis H between the back-and-forth sweeping extracted for the same capacity; (C) the slope S of the forward stroke curve calculated between a capacity of 5×10⁻¹⁰ F and 8×10⁻¹⁰ F.

FIGS. 6A and 6B represent a graph of the electrical features of the electronic component illustrated in FIG. 3, for different gases from which the plasma is formed, according to different examples of embodiment of the method.

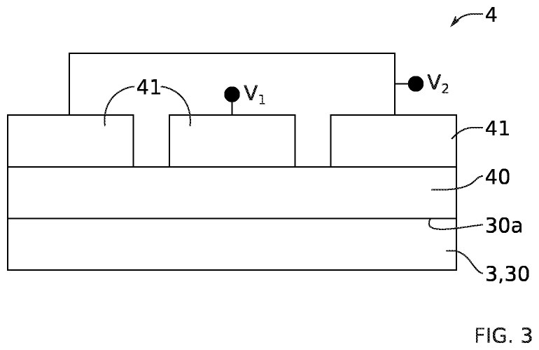

The drawings are given as examples, and are not limiting of the invention. They constitute principle schematic representations intended to facilitate the understanding of the invention, and are not necessarily to the scale of practical applications. In particular, in FIGS. 2 and 3, the thicknesses of the different layers are not representative of reality.

### DETAILED DESCRIPTION OF THE INVENTION

Before starting a detailed review of embodiments of the invention, optional features are stated below, which can optionally be used in association or alternatively.

According to an example, the method comprises the manufacturing of the structure. According to an example, the structure is a layer.

According to another example, the structure cannot be a layer. It can comprise a nanostructure or a plurality of nanostructures. A nanostructure is a structure, at least one dimension of which is less than 1 millimetre and preferably less than 500 nm (10⁻⁹ metres) and preferably less than 100 nm. A nanostructure can be three-dimensional (3D). It can, for example, be a terminal or a wire extending in a main direction, perpendicular to a face of the support substrate and having, in a plane perpendicular to this main direction, a cross-section less than 1 millimetre, preferably less than 500 nm, and preferably less than 100 nm. The nanostructure can also be a trench or a ridge. It can also be a structure intended to form part or to form a device such as a transistor or a micromechanical or electromechanical device (MEMS, NEMS, etc) or also a optical or optoelectronic device (MOEMS, etc.). The nanostructure is specific. It does not extend over the entire substrate. Thus, a face of the substrate extends mainly in a plane and nanostructures extend from this face and in a direction perpendicular to this plane. These nanostructures are therefore discontinuous.

According to an example, V_{bias-substrate} and Vₚₗₐₛₘₐ are independent.

According to an example, V_{bias-substrate} and Vₚₗₐₛₘₐ are controlled independently.

According to an example, the bias voltage V_{bias-substrate} is applied to the plate. Preferably, the bias voltage V_{bias-substrate} is applied only to the plate.

According to an example, the bias voltage V_{bias-substrate} is non-zero.

According to an example, the absolute value of the bias voltage |V_{bias-substrate}| IS substantially greater than or equal to 0 Volts, preferably greater than or equal to 10 Volts. According to an example, the absolute value of the bias voltage | V_{bias-substrate}| is substantially less than or equal to 130 Volts. According to an example, the absolute value of the bias voltage |V_{bias-substrate}| is substantially between 0 Volts and 130 Volts, preferably between 10 Volts and 130 Volts. Preferably, the absolute value of the bias voltage |V_{bias-substrate}| IS substantially equal to 40 Volts. These V_{bias-substrate} values make it possible to obtain an energy from the ions of the plasma, particularly adapted to improve the effectiveness of the cleaning of the surface of the exposed layer. An interface of particularly good quality is thus obtained.

According to an example, the bias voltage V_{bias-substrate} is applied during at least 70% of the duration T_{P} for forming the plasma, preferably at least 90%. According to an example, the bias voltage V_{bias-substrate} is applied for the whole duration T_{P} for forming the plasma.

According to an example, the at least one injected gas in nitrogen-, hydrogen-, ammoniac-, argon-, helium-based, or with a basis of a mixture of them. Neutral gases such as argon or helium can have a physical effect of controlled bombardment of the surfaces leading to an improvement of the quality of the interfaces by the method. Nitrogen and hydrogen can have a physical, and also chemical effect, in particular at the gaps of the III-V material, for example in a GaN network.

According to an example, the at least one injected gas is with a basis of at least one from among nitrogen and hydrogen, preferably the at least one injected gas comprises dinitrogen, dihydrogen, ammoniac, argon or a mixture of them.

According to an example, the injected gas is a mixture of dinitrogen and dihydrogen. It has been observed, during the development of the invention, that this mixture made it possible to improve the electrical properties of the electronic component obtained.

According to an example, the at least one injected gas comprises dihydrogen. The fraction of dihydrogen can be substantially greater than 1%. The fraction of dihydrogen can be substantially less than 99%. The fraction of dihydrogen can be substantially between 1% and 99%, preferably substantially equal to 33%.

According to an example, the duration of the formation of the plasma is substantially greater than 7 seconds, preferably substantially greater than or equal to 10 seconds. According to an example, the duration of the formation of the plasma is substantially equal to 15 seconds.

According to an example, the duration of the purge is substantially greater than or equal to 1 second, preferably substantially greater than or equal to 3 seconds. According to an example, the duration of the purge is substantially equal to 6 seconds.

According to an example, the cleaning of the surface comprises a number of cycles less than or equal to 20 cycles, preferably less than or equal to 10 cycles. Thus, the electrical properties of the electronic component obtained are also improved.

According to an example, the cleaning cycle only comprises the purge, the injection of the gas and the formation of the plasma from this gas. The cycle preferably has no additional injection of additional gas during which no plasma is generated.

According to an example, the cleaning of the surface comprises a number of cycles greater than or equal to 3 cycles, preferably greater than or equal to 5 cycles, preferably greater than 10 cycles.

According to an example, the formation of the plasma is done by a remote source.

Thus, the energy of the ions is better controlled, which ensures a good effectiveness of the cleaning and a good reproducibility of the method.

Preferably, the source is an inductive radiofrequency source. According to an example, during the formation of the plasma, the power of the inductive radiofrequency source is between 100 W and 300 W, preferably 300 W.

According to an example, during the formation of the plasma, and preferably during the cleaning, the temperature of the substrate is substantially between 200° C. and 350° C. Preferably, the temperature of the substrate is substantially equal to 300° C. According to an example, the temperature of the substrate is substantially equal to the deposition temperature of the second layer.

According to an example, the pressure in the reaction chamber is less than or equal to 50 mTorr, preferably equal to 10 mTorr, at least during the formation of the plasma, preferably during cleaning.

According to an example, each cycle comprises at least one stabilisation of the gases injected in the reaction chamber. The stabilisation is preferably achieved at least before the formation of the plasma.

According to a particular example, each cycle only comprises the steps of purging, stabilising and forming the plasma.

According to an example, the structure is taken from among: a layer, a three-dimensional structure, a plurality of three-dimensional structures.

According to an example, the exposed layer is with a basis of or made of a III-N material. According to an example, the exposed layer is with a basis of or made of gallium nitride.

According to an example, the second layer deposited on the cleaned surface is with a basis of a dielectric material, for example of a metal oxide or of a metal nitride, for example alumina-based. According to an example, the second layer deposited on the cleaned surface is with a basis of a semiconductive material, for example with a basis of a III-V material, and preferably aluminium nitride-based.

According to an example, the microelectronic component is a transistor, an active layer of which is the layer with a basis of a cleaned III-V material, preferably the microelectronic component is a power transistor, and more preferably, a HEMT-type transistor.

According to an example, the microelectronic component is a light-emitting diode. According to an example, the microelectronic component being a light-emitting diode, the second layer deposited on the cleaned surface is with a basis of a semiconductive material.

By a substrate, a film, a layer, a gaseous mixture, a plasma “with a/the basis” of a species A or “species A-based”, this means a substrate, a film, a layer, a gaseous mixture, a plasma comprising this species A only or this species A, and optionally other species. Thus, a substrate comprising a structure with an exposed layer can be:
either, preferably, a stack wherein the structure is a layer deposited on a support layer,
or a stack only comprising the structure. In this case, the structure can be self-supporting, i.e. that it supports its own weight.

Moreover, a nitrogen- and/or hydrogen-based plasma can be based on a chemistry only comprising nitrogen and/or hydrogen or comprising nitrogen and/or hydrogen and optionally one or more other species, for example, neutral gases.

Fully conventionally, a structure with a basis of a III-V material is a structure made, or comprising a material comprising at least one species of column III of the periodic table and at least one species of column V of this table. Likewise, a structure with a basis of a III-N material is a structure made, or comprising a material comprising at least one species of column III of the periodic table and nitrogen (N). A III-N material can therefore, for example, be taken from among GaN, AlGaN, AlInGaN, InN.

Fully conventionally, a structure with a basis of a metal oxide is a structure made, or comprising a material comprising at least one metal or one metalloid and oxygen. A structure with a basis of a metal nitride is a structure made or comprising a material comprising at least one metal or one metalloid and nitrogen.

Several embodiments of the invention implementing successive steps of the manufacturing method are described below. Unless explicitly mentioned otherwise, the adjective “successive” does not necessarily imply, even if this is generally preferred, that the steps immediately follow one another, intermediate steps being able to separate them.

Moreover, the term “step” means the carrying out of some of the method, and can mean a set of substeps.

Moreover, the term “step” does not compulsorily mean that the actions carried out during a step are simultaneous or immediately successive. Certain actions of a first step can, in particular, be followed by actions linked to a different step, and other actions of the first step can then be resumed. Thus, the term “step” does not necessarily mean single and inseparable actions over time and in the sequence of phases of the method.

The word “dielectric” qualifies a material, the electrical conductivity of which is sufficiently low in the given application to serve as an insulator. In the present invention, a dielectric material preferably has a dielectric constant greater than 4.

In the present patent application, when a gaseous mixture is expressed with percentages, these percentages correspond to fractions of the total flow rate of the gases injected into the reactor. Thus, if a gaseous mixture, for example intended to form a plasma, comprises x % of the gas A, this means that the injection flow rate of the gas A corresponds to x % of the total flow rate of the gases injected into the reactor to form the plasma.

In the present invention, by “HEMT-type transistors”, this means High Electron Mobility Transistor-type transistors, sometimes called heterostructure field effect transistors. Such a transistor includes the superposition of two semiconductive layers having different band gaps which form a quantum well at their interface. Electrons are confined in this quantum well to form a two-dimensional electron gas. For reasons to maintain at a high voltage and at a high temperature, the materials of these transistors are chosen so as to have a wide energy band gap.

By microelectronic device, this means any type of device made with microelectronic means. These devices in particular in addition include devices with a purely electronic purpose, micromechanical or electromechanical devices (MEMS, NEMS, etc.), as well as optical or optoelectronic devices (MOEMS, LED, etc.).

This can be a device intended to ensure an electronic, optical, mechanical function, etc. This can also be an intermediate product, only intended to produce another microelectronic device.

It is specified that in the scope of the present invention, the thickness of a layer or of the substrate is measured in a direction perpendicular to the surface, according to which this layer or this substrate has its maximum extension. The thickness is thus taken in a direction perpendicular to the main faces of the substrate on which the different layers rest. In the case of a three-dimensional element, for example a pattern of the structure, the thickness of a layer extending over a flank of this element can be measured perpendicularly to this flank.

It is specified that, in the scope of the present invention, the terms “on”, “surmounts”, “covers”, “underlying”, “opposite” and their equivalents do not necessarily mean “in contact with”. Thus, for example, the deposition, the transfer, the bonding, the assembly or the application of a first layer on a second layer does not compulsorily mean that the two layers are directly in contact with one another, but means that the first layer covers at least partially, the second layer by being either directly in contact with it, or by being separated from it by at least one other layer or at least one other element.

By a parameter “substantially equal to/greater than/less than” a given value, this means that this parameter is equal to/greater than/less than the given value, plus or minus 10% of this value. By a parameter “substantially between” two given values, this means that this parameter is, as a minimum, equal to the smallest given value, plus or minus 10% of this value, and as a maximum, equal to the largest given value, plus or minus 10% of this value.

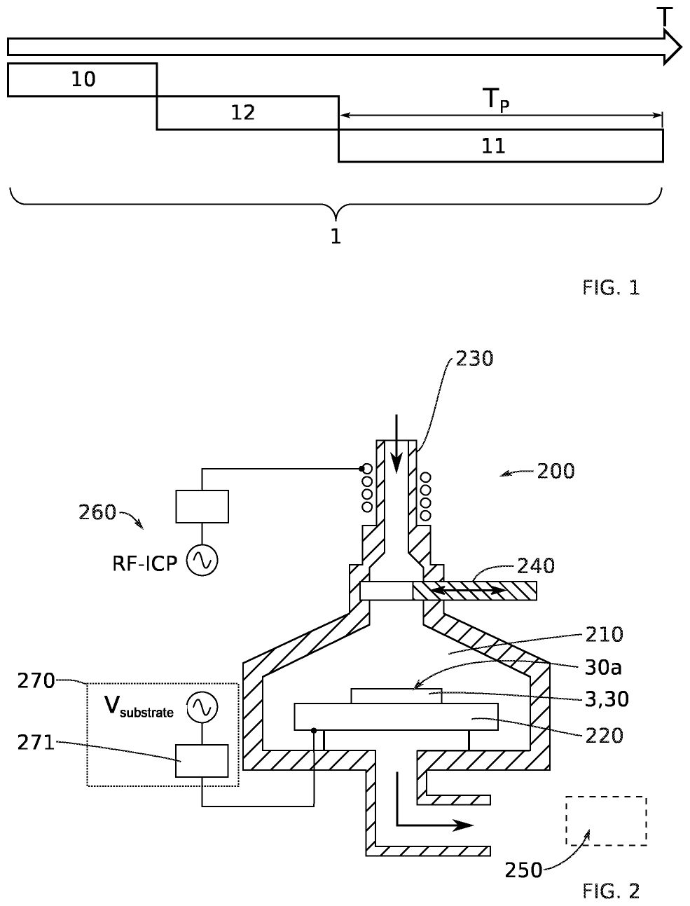

The general principle of the present invention will now be described in reference to FIG. 1.

FIG. 1 illustrates the different steps of a cyclic plasma treatment cycle 1. During the cleaning of the surface 30a of the exposed layer 30, this cycle 1 of steps is repeated several times.

Each cycle 1 comprises a sequence of purging 10 and of forming a plasma 11 in a plasma reactor 200. This reactor can be a deposition plasma reactor such as that illustrated in FIG. 2 and which will be described below. Preferably, this is a reactor configured to perform atomic layer depositions (PEALD). In order to proceed with these cycles 1, a substrate is disposed, in a reaction chamber 210 of the reactor 200, comprising a structure 3 comprising an exposed layer 30 with a basis of a III-V material and having a surface 30a.

Such a structure is, for example, with a basis of a III-N material. In the non-limiting example which will be described in detail, this structure is with a basis of or made of GaN. More specifically, this structure will be described as being a GaN layer. All the features, steps and technical effects which will be described below are fully applicable to a structure with a basis of or made of a III-V material other than GaN. Moreover, all the features, steps and technical effects which will be described below, are fully applicable to a structure, possibly other than a layer, such as a nanostructure, for example three-dimensional, or a plurality of such structures.

The substrate can be formed only of this III-V material structure 3. Alternatively, this substrate can comprise a support layer surmounted by at least one such structure 3. The structure has a free surface 30a, exposed to the species present in the reaction chamber 210.

Each cycle 1 comprises at least two, and preferably three, main steps. Each cycle comprises a step 10, usually qualified as a purge step. The purge 10 has the function of discharging the gaseous species optionally present in the reaction chamber 210, for example of discharging the reactional subproducts following the plasma treatment. According to an example, in the cycle 1, the purge is done before the formation of the plasma 11. Thus, the composition of the plasma 11 formed is better controlled, to ensure the quality of the plasma obtained. This purge 10 generally consists of injecting, into the reaction chamber 210, a neutral gas such as argon (Ar).

Each cycle 1 further comprises an injection of at least one gas into the reaction chamber 210 and a formation of a plasma 11 from this gas. During the formation of the plasma 11, the gases are preferably injected continuously. Each cycle comprising an alternance of a purge 10 and the formation of a plasma 11, and this cycle being repeated several times during the cleaning, the application of the plasma is fractional over time. This treatment is therefore referred to by the term of “cyclic plasma”, opposite to a treatment where the cleaning is done by an application of a plasma continuously.

During the formation of the plasma 11, a bias voltage V_{bias-substrate} is applied to the substrate, for example via a voltage regulation device such as a radiofrequency power generator. The bias voltage of the substrate can be zero, which is not equivalent to not applying a voltage to the substrate. For example, the substrate can be intrinsically biased to a voltage different from 0. It is understood that a bias voltage can be applied to the substrate, such that V_{bias-substrate} is zero. Moreover, the experimental results which will be presented below show that even at 0V, the advantages linked to the application of a bias voltage V_{bias-substrate} can actually be seen. The bias voltage V_{bias-substrate} can, for example, be strictly less than 0 (<0V). This bias voltage V_{bias-substrate} applied to the substrate is distinct from the potential of the plasma Vₚₗₐₛₘₐ. The bias voltage V_{bias_substrate}, is indeed distinguished from the potential of the plasma Vₚₗₐₛₘₐ which is induced, fully conventionally by the plasma source, in order to generate ions and radicals, and therefore initiate the dielectric deposition. The bias voltage V_{bias_substrate} is controlled independently from the potential of the plasma Vₚₗₐₛₘₐ induced by the source. The bias voltage V_{bias-substrate} is more specifically applied to a plate for receiving the substrate. “Applied to the substrate” means that the bias voltage V_{bias-substrate} is applied to the plate which supports the substrate 3, preferably which is in contact with the substrate, whether the substrate 3 is conductive or not. In practice, as for example illustrated by FIG. 2, the reaction chamber 210 comprises a plate 220 for receiving the substrate. This plate can also be qualified as a sample holder. According to an example, the bias voltage V_{bias-substrate} is applied to the plate. Preferably, the bias voltage V_{bias-substrate} IS applied only to the plate. According to this example, the plate 220 is electrically conductive and the bias voltage V_{bias-substrate} is applied to this plate 220 by a voltage regulation device 270 to be transmitted to the substrate 3.

The application of this bias voltage V_{bias-substrate}, provides considerable advantages. In particular, this bias makes it possible to modulate the energy of the ions from the plasma in a controlled manner, thanks to the regulation device 270. In a non-collisional sheath, the energy of the ions indeed depends on the potential of the plasma and on the bias voltage of the substrate, according to the following relationship:

$${E}_{ion} = q ( {V}_{plasma} - {V}_{bias - substrate} )$$

with q the ion charge.

By applying a bias voltage V_{bias-substrate}, the effectiveness of the ion bombardment on the surface can be increased, while preserving the exposed surface 30a. The cleaning of the surface is thus improved, and consequently, the quality of the interface between the exposed III-V material layer 30a and a subsequent layer 40 is improved. Its repeatability is further improved with respect to the existing solutions, in particular those resorting to the potential of the plasma Vₚₗₐₛₘₐ induced by the plasma source to modulate the ion bombardment which are, in practice, difficult to control to obtain a repeatable result.

The absolute value of the bias voltage |V_{bias-substrate}| applied is less than 160V (volts), preferably less than 130V. It will be noted that this bias voltage is lower than the bias voltages usually used to perform plasma etchings or plasma implantations. Furthermore, this method is preferably implemented in a deposition plasma reactor. The etching plasma reactors are not configured to apply bias voltages which are as low to the substrate. Preferably, the absolute value of the bias voltage |V_{bias-substrate}| is between 0 Volts and 130 Volts, for example is between 10 Volts and 130 Volts, preferably substantially 40 Volts. During the development of the invention, it has indeed been highlighted that an absolute value of bias voltage |V_{bias-substrate}| substantially equal to 40 Volts was particularly effective to improve the quality of the interface with the subsequent layer 40, and consequently, the electronic properties of the microelectronic component obtained.

The bias voltage V_{bias-substrate} is applied for at least 70% of the duration T_{P} of formation of the plasma 11, preferably at least 90%, and even more preferably, for the entire duration T_{P} of formation of the plasma 11. According to an example, the bias voltage V_{bias-substrate} IS applied only during the formation of the plasma 11.

Preferably, prior to the formation of the plasma 11, the cycle 1 comprises a phase of stabilising 12 the injected gases. This phase is, in particular, configured to stabilise the flow rate of the gases injected into the reaction chamber 210. During this stabilisation 12, the gases are injected into the reaction chamber 210 without formation of the plasma, preferably until stabilisation of their injection flow rate. Thus, the subsequent formation of the plasma 11 is better controlled.

According to an example, during the formation of the plasma 11, the pressure in the reaction chamber 210 is less than or equal to 50 mTorr, preferably equal to 10 mTorr (with 1 Torr=1 mmHg≈133.322 Pa, in a known manner in the field of plasma treatments). Thus, the pressure of the chamber during the plasma is adjusted so as to have a non-collisional sheath. At these low pressures, the average free path of the ions is greater than the thickness of the sheath of the plasma. Thus, the ions are accelerated through the sheath, without suffering collisions. The pressure in the reaction chamber 210 can, in particular, be adjusted according to the injected gas flow rate and the suctioning by the pump 250.

According to an example, the injected gas(es) flow rate is substantially between 5 and 100 sccm (unit of standard cubic centimetres per minute, and commonly used in the field for measuring the flow rate of a gas). Preferably, the injected gas(es) flow rate is substantially equal to 30 sccm.

FIG. 2 illustrates a diagram of a plasma reactor 200 which can be used to implement the method. Preferably, the method is implemented in a deposition plasma reactor, in particular to enable the deposition of a dielectric, just after the cleaning of the exposed layer. According to an example, the reactor 200 comprises a plasma source 260 which is remote with respect to the reaction chamber 210. Thus, the potential of the Vₚₗₐₛₘₐ is remote from the substrate. The effect of the bias voltage V_{bias-substrate} increases the energy of the ions from the plasma at the substrate. In the absence of V_{bias-substrate}, for a zero voltage, the energy of the ions is equal to the product of the charge of the ion by the potential of the plasma Vₚₗₐₛₘₐ. The effectiveness of the ion bombardment on the surface 30a can thus be better controlled than with respect to a non-remote source or a remote source, which is not associated with the application of a bias voltage V_{bias-substrate}, for example by a second device for regulating the voltage of the substrate. The repeatability of the cleaning is consequently improved. Furthermore, the use of a remote source makes it possible to avoid any direct contact between the plasma in its formation zone and the substrate, being able to damage the substrate. The use of a remote plasma source further minimises the directivity of the plasma treatment. The treatment of a three-dimensional structure 3, in particular of a nanostructure, is facilitated.

More specifically, the method is implemented in an inductively coupled plasma reactor, usually qualified by ICP (Inductively Coupled Plasma). Preferably, the source is a radiofrequency inductive source, which makes it possible to have a stable plasma at a lower power with respect to other sources, for example, a microwave source, of typically 1500 W to 2000 W. According to an example, the power of the inductive radiofrequency source is between 100 and 300 W, preferably 300 W. The more the power of the inductive radiofrequency source is increased, the more the ion flow being able to reach the substrate increases.

The reactor 200 comprises a reaction chamber 210 inside which, a plate 220 is disposed. This plate 220 is configured to receive the substrate comprising the structure 3. The substrate rests on the plate 220 by a rear surface. The front surface 30a of the structure 3 is exposed to the species present in the reaction chamber 210. In this non-limiting example, the substrate forms the structure 3, of which it is sought to clean the exposed surface 30a. The front surface of the substrate therefore constitutes the surface 30a of the structure 3. The plate 220 is electrically conductive. Relatively conventionally, the reactor comprises a gas inlet 230, making it possible to inject gases intended to form the chemistry of the plasma inside the chamber 210, as well as gases intended for the purge phases 10. The plasma source 260 is, according to an example, an induction coupling device 260, a coil of which is illustrated in FIG. 2, and which enables the formation of the plasma. The reactor 200 also comprises an insulation valve 240 of the reaction chamber 210. The reactor 200 also comprises a pump 250 to control the pressure inside the reaction chamber 210 synergically with the flow rate of the injected gases, and to extract the species present in the reaction chamber 210.

Advantageously, this reactor 200 comprises a bias device 270 configured to enable the application of the bias voltage V_{bias-substrate} to the plate 220, for example via a radiofrequency power generator. This voltage can ultimately be applied to the substrate 3, all at least to its rotated face, facing the plate 220, whether this face is electrically conductive or not. This bias device 270 is preferably distinct from the plasma source 260. This bias device 270 comprises a control device 271 and makes it possible to apply an alternating voltage onto the plate 220. Preferably, this control device 271 comprises an auto match unit, which adapts the impedance in the chamber and of the ion source to that of the radiofrequency generator. This bias device 270 is configured to enable the application to the plate 220 of the bias voltage V_{bias-substrate}, the amplitude of which is low, typically less than 160 Volts, preferably less than 130 volts.

The bias device 270 and the plasma source 260 are configured so as to be able to adjust the bias voltage V_{bias-substrate} applied to the plate 220 independently of the potential of the plasma Vₚₗₐₛₘₐ. V_{bias-substrate} and Vₚₗₐₛₘₐ are independent. V_{bias-substrate} and Vₚₗₐₛₘₐ are controlled independently.

According to an example, the second layer 40 is directly deposited on the cleaned surface. The second layer 40 can be deposited by the reactor 200, and more specifically, without removing the substrate 3 from the chamber 210 between the cleaning and the deposition of this layer. Thus, a possible degradation of the quality of the interface being able to be induced by this removal is avoided. The deposition of this layer 40 can be done, by depositing atomic layers, and preferably by depositing plasma enhanced atomic layers. The second layer 40 can be with a basis of or made of a material with a basis of a chemical element chosen from among an element of column III and an element of column V of the periodic table and/or with a basis of a metal oxide. For example, the second layer 40 can be silica SiO₂-based. The second layer 40 can be with a basis of or made of a dielectric material, for example hafnium oxide HfO₂-based, and preferably alumina-based.

The effects of the method on the electrical performance of a microelectronic component 4 are now described in reference to FIGS. 3 to 5. The study of the effect of the plasma treatments on an exposed GaN layer 30 has been done, thanks to Capacitance-Voltage electrical measurements on a Metal-Insulator-Semiconductor-type component (commonly abbreviated to CAPAMIS), schematically illustrated in FIG. 3. To obtain the component 4, a GaN layer 30 is deposited on a silicon substrate and comprises a 100 nm thick NID-GaN superficial layer (NID meaning “Non-intentionally doped”) deposited on an n-GaN 1 μm layer, doped at 5·10¹⁷ cm⁻².

Once the cleaning of the surface 30a of the superficial layer 30 is done, the samples have been covered by an alumina layer 40 done in-situ by atomic layer deposition (ALD). The alumina layer 40 is obtained thermally during the deposition with water vapour as an oxidising source. Nickel then gold electrical contacts 41 are then deposited. The same experimental conditions are used for all the studies, unless mentioned otherwise.

The components 4 are characterised by “Capacitance-Voltage” (C-V)-type electrical measurements at a frequency of 10 kHz and on a terminal size of 600 μm. In FIG. 3, V₁ indicates a high voltage and V₂ indicates a low voltage to represent the polarities to take the C-V measurements.

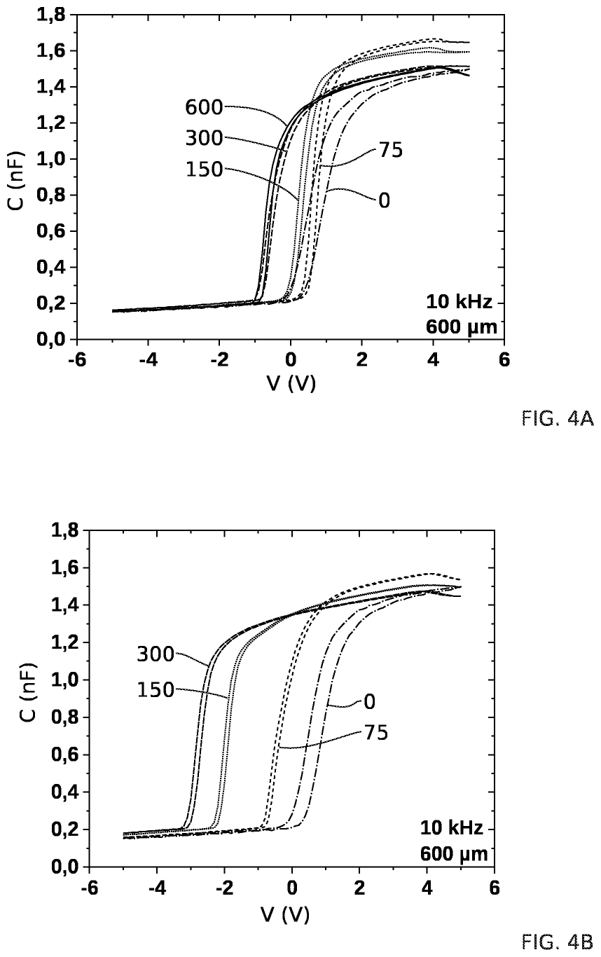

FIGS. 4A and 4B are graphs which respectively illustrate the cyclic plasma effect (4A) with respect to a continuous plasma (4B), for a zero bias voltage.

FIGS. 4A and 4B compare the effect of a cyclic or continuous plasma of chemistry N₂—H₂ with application of a bias voltage V_{bias-substrate} on the electrical performance of the CAPAMIS. In this example, per cycle of the cyclic plasma, the plasma 11 duration is 15 s and the purge 10 duration is 6 s. The total duration of the plasma for all of the repeated cycles is equal to the duration of the continuous plasma applied onto the components, and its duration in seconds is indicated for each curve. For FIG. 4A, the plasma duration per cycle is 15 s, that is a number of cycles of 0, 5, 10, 20 and 40. The curves labelled 0 correspond to curves without plasma cleaning. The parameters of the chemistry of the plasma, purge 10 and formation t of the plasma 11 are described below.

Between a cyclic plasma and a continuous plasma with application of a zero bias voltage V_{bias-substrate}, a first difference is the induced heating of the substrate 3. A continuous plasma can induce a significant increase of the temperature of the substrate, while a cyclic plasma, the purge phases 10 enable its cooling between each phase of forming the plasma 11. The cyclic plasma therefore offers a better preservation of the structure 3, while enabling an effective cleaning of its surface.

Another notable difference can be observed at the voltage offsetting of the curves and of the slope in the desertion system. Under the same experimental conditions, a continuous plasma treatment induces an offsetting of the C-V curves to negative voltages, and therefore a decrease of the threshold voltage to negative values. Thus, to quantify these variations, the voltage of the forward stroke curve (V₃) taken for a capacity taken arbitrarily at 8·10⁻¹⁰ F, the hysteresis (H) between the back-and-forth sweeping for the same capacity and finally the slope of the forward stroke curve (S) taken between a capacity of 5 and 8·10⁻¹⁰ F, are extracted from the C-V curves.

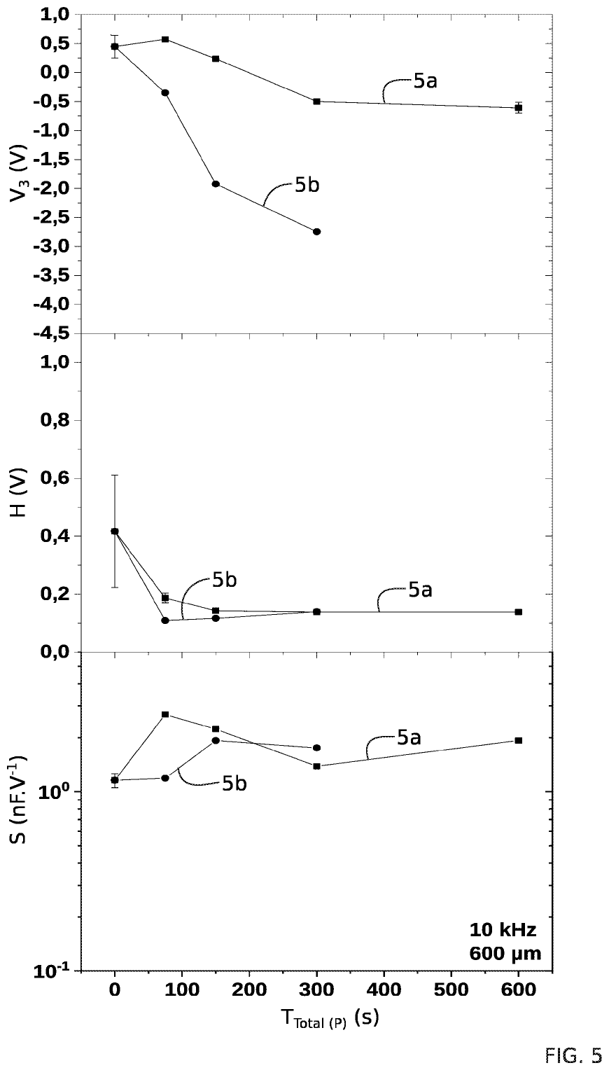

These parameters are grouped together in FIG. 5, which is now described. The curves 5a correspond to cyclic plasmas and the curves 5b correspond to continuous plasmas. For a cyclic plasma, the voltage V₃ stagnates up to a total plasma duration of 75s (that is 5 cycles), decreases progressively then finishes by reaching a new plate for durations greater than 300 s (that is 20 cycles). Conversely, for a continuous plasma, this voltage V₃ suddenly and monotonously falls when the plasma duration increases. Moreover, for a continuous or cyclic plasma, and whatever its duration, all at least up to 600 s, the hysteresis H is improved and is less than 0.2V. For a cyclic plasma, the slope S is improved up to a duration of 75s, then is slightly degraded up to reaching a plate. For a continuous plasma, it is constant for low plasma durations, is improved and stagnates beyond 150 s. With application of a zero bias voltage V_{bias-substrate}, a continuous plasma or a cyclic plasma therefore makes it possible for each to considerably reduce the hysteresis and to improve the slope S of the CAPAMIS. However, major disparities between these two plasmas appear at the offsetting of the voltage features. Indeed, a continuous plasma treatment generates a systematic offsetting of the C-Vs to negative voltages. It is today considered that the underlying mechanism is probably linked to the formation, to the interface, of positive fixed charges, the density of which would be correlated to the voltage offsetting and would thus highly increase with the plasma duration. However, as has been stated in the introduction, this voltage decrease is to be avoided for numerous microelectronic components, in particular for the preparation of “Normally-Off” HEMT-type transistors.

Unexpectedly, in the scope of the development of the present invention, it has been observed that a cyclic plasma coupled with the application of a bias voltage offers the same advantages in terms of slope and hysteresis, while also limiting the systematic and negative voltage offsetting of C-Vs.

### Particular Examples and Variants of Embodiments

The paragraphs below aim to describe particular examples of embodiments of the present invention, and to propose certain variants. The features and the examples and variants proposed below are applicable and can be combined with each of the examples mentioned.

In reference to FIGS. 4A and 5, it can be observed that the total duration of formation of the plasma T_{Total(P)} has an impact on the cleaning of the GaN layer. According to an example, the cleaning of the surface comprises a number of cycles less than or equal to 20 cycles, and preferably less than or equal to 10 cycles. Preferably, the total duration of the plasma, i.e. the duration of formation of the plasma 11 over all of the repeated cycles is less than 150 s, and preferably less than 100 s. Thus, an optional offsetting of the C-V curves and therefore of the threshold voltage is also minimised.

According to an example, the duration of formation of the plasma is greater than 7 seconds, preferably greater than or equal to 10 seconds, and preferably equal to 15 seconds. The plasma duration is thus sufficiently long to enable an effective cleaning of the layer, while limiting the heating of the structure 3.

The duration of the purge 10 is substantially greater than or equal to 1 second. Preferably, the duration of the purge 10 is substantially greater than or equal to 3 seconds, and more preferably, substantially equal to 6 seconds. The purge phase is thus sufficiently long to remove the subproducts from the reaction between the plasma and the surface 30a of the treated layer.

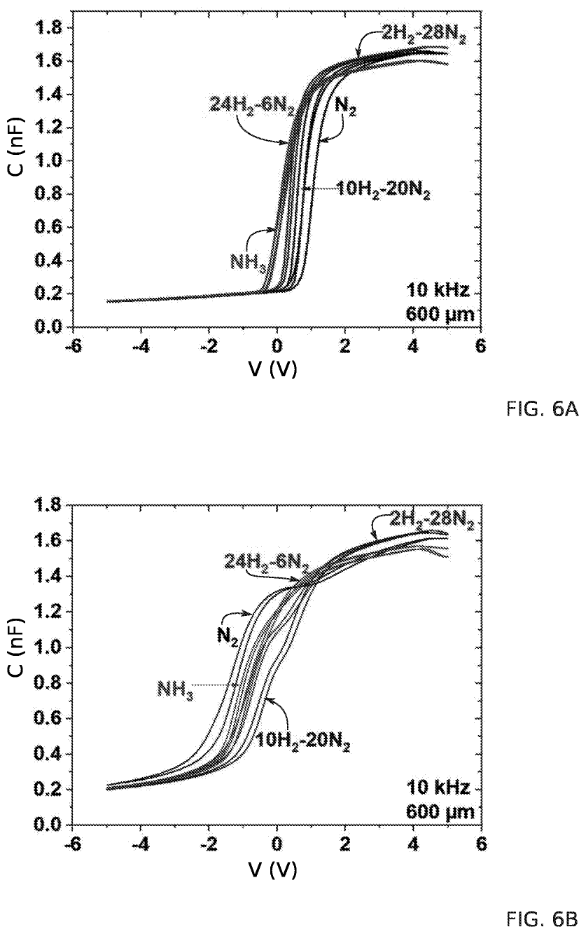

The effect of the chemistry of the plasma is now discussed in reference to FIGS. 6A and 6B. FIGS. 6A and 6B compare the effect of a cyclic plasma on the electrical performance of the CAPAMIS, on a GaN layer formed by epitaxy (6A) or on an etched GaN layer (6B), for different plasma chemistries, for a number of cycles of 5, the plasma duration per cycle being 15 s, that is a total plasma duration of 75s. The total gas flow rate has been fixed at 30 sccm to keep the residence time of the species formed during the formation of the plasma 11 in the reaction chamber 210 constant.

The injected gas, or the mixture of injected gases, can be with a basis of at least one from among nitrogen and hydrogen. Preferably, the at least one injected gas comprises dinitrogen, dihydrogen, ammoniac, argon or a mixture of them.

The injected gas, or the mixture of injected gases, can be nitrogen- and hydrogen-based. It has been observed that a cyclic plasma treatment with a basis of a mixture of dinitrogen N₂ and of dihydrogen H₂, or of ammoniac NH₃ made it possible to decrease the hysteresis of the C-V curves with respect to a dinitrogen-based plasma without hydrogen, as illustrated by FIGS. 6A and 6B.

According to an example, the injected gas is a mixture of dinitrogen and of dihydrogen. During the development of the invention, it has been highlighted, unexpectedly, that a plasma formed from a mixture of dinitrogen and of dihydrogen was particularly advantageous for the cleaning of the surface of a GaN layer, by limiting, in particular, the offsetting of the C-V curves, and therefore of the threshold voltage, to negative values, as illustrated by FIGS. 6A and 6B. An explanation considered for that would be a better effectiveness of a plasma of an N₂—H₂ mixture to clean the surface of the GaN, passivating the nitrogen gaps of the GaN and filling the dangling bonds. Jointly with a sufficient plasma duration, the plasma treatment makes it possible to also improve the nitridation of the surface of the GaN layer.

According to an example, the dihydrogen fraction is substantially between 1% and 99%, preferably substantially equal to 33%. Very low hysteresis have been observed for a dihydrogen fraction of substantially 7% (2H₂-28N₂) at 80% (24H₂-6N₂). The lowest offsetting of the C-V curves has been observed for a dihydrogen fraction of substantially 33% (10H₂-20N₂).

In view of the description above, it clearly appears that the invention proposes a solution improving the interface of a material layer of the III-V type, and more specifically, III-N and a consecutively deposited layer.

The invention is not limited to the embodiments described above and extends to all the embodiments covered by the invention. The present invention is not limited to the examples described above. Plenty of other variants of embodiments are possible, for example by combining features described above, without moving away from the scope of the invention. Furthermore, the features described relative to an aspect of the invention can be combined with another aspect of the invention.

For example, in the preceding examples, the exposed GaN-based layer is constituted of GaN. However, the present invention also extends to the embodiments, wherein the GaN-based layer is a layer with a basis of a III-V material. Preferably, this is a III-N material. The layer with a basis of a III-N material can comprise at least one from among indium and aluminium. For example, this GaN-based layer can be GaN, AlGaN, InGaN or AlInGaN. Thus, all the examples, features, steps and technical advantages mentioned above in reference to a GaN-based structure are applicable to a structure with a basis of a material taken from among III-V materials.

For example, in the preceding examples, the second layer is constituted of alumina. However, the present invention also extends to the embodiments wherein the second layer is with a basis of a metal oxide and/or with a basis of a chemical element, chosen from among an element of column III and an element of column V of the periodic table. Thus, all the examples, features, steps and technical advantages mentioned above in reference to a second alumina layer are applicable to a second layer with a basis of a metal oxide and/or with a basis of a chemical element chosen from among an element of column III and an element of column V of the periodic table.

The invention also extends to the embodiments, wherein the structure is deposited on a silicon-based substrate.

Moreover, in the examples described above, the structure is a layer. However, all the examples, features, steps and technical advantages mentioned above in reference to a structure forming a layer are applicable to a structure not forming a layer, but forming a specific structure, for example a three-dimensional raised part. The structure can be a nanostructure or comprise a plurality of nanostructures. The second layer can be a nanostructure or comprise a plurality of nanostructures.

1. A method for preparing a microelectronic component comprising:
providing a structure comprising an exposed layer with a basis of a III-V material having a surface, in a plasma reactor comprising a reaction chamber inside which a substrate comprising the structure is disposed,
cleaning the surface of the exposed layer by a cyclic plasma treatment comprising several treatment cycles, each treatment cycle comprising at least:
purging the reaction chamber, and
injecting at least one a nitrogen-, hydrogen-, ammoniac-, argon-, helium-based gas or a mixture of them in the reaction chamber and forming a plasma from the gas or mixture in the reaction chamber, wherein the plasma is generated at a plasma potential, and during which a bias voltage is applied to the substrate, and the plasma potential being controlled independently, and
depositing, on the cleaned surface, a second layer of a material based upon at least one of:
at least one chemical element chosen from among an element of column III and an element of column V of the periodic table, and
a metal oxide.

2. The method according to claim 1, wherein an absolute value of the bias voltage is between 0 Volts and 130 Volts.

3. The method according to claim 1, wherein the bias voltage is applied for at least 70% of a duration of formation of the plasma.

4. The method according to claim 1, wherein the at least one injected gas is based upon at least one of nitrogen and hydrogen.

5. The method according to claim 4, wherein the injected gas is a mixture of dinitrogen and dihydrogen.

6. The method according to claim 1, wherein the at least one injected gas comprises dihydrogen, and a dihydrogen fraction is between 1% and 99%.

7. The method according to claim 1, wherein a duration of formation of the plasma is greater than 7 seconds and less than or equal to 15 seconds.

8. The method according to claim 1, wherein a duration of the purge is greater than or equal to 1 second and less than or equal to 6 seconds.

9. The method according to claim 1, wherein the cleaning of the surface comprises a number of cycles less than or equal to 20 cycles.

10. The method according to claim 1, wherein the cleaning of the surface comprises a number of cycles greater than or equal to 3 cycles.

11. The method according to claim 1, wherein forming the plasma comprises using a remote source.

12. The method according to claim 1, wherein
forming the plasma comprises using an inductive radiofrequency source, and
a power of the inductive radiofrequency source is between 100 and 300 W.

13. The method according to claim 1, wherein during at least one of forming the plasma and the cleaning, a temperature of the substrate is between 200 and 350° C.

14. The method according to claim 1, wherein during forming the plasma, a pressure in the reaction chamber is less than or equal to 50 mTorr.

15. The method according to claim 1, wherein each treatment cycle comprises at least one stabilisation of the gases injected into the reaction chamber, the stabilisation being performed at least before forming the plasma.

16. The method according to claim 1, wherein the structure comprises one of a layer, a three-dimensional structure, and a plurality of three-dimensional structures.

17. The method according to claim 1, wherein the exposed layer is based upon a III-N material.

18. The method according to claim 17, wherein the exposed layer is based upon gallium nitride.

19. The method according to claim 1, wherein the second layer deposited on the cleaned surface is based upon a dielectric material.

20. The method according to claim 1, wherein the microelectronic component is a transistor, an active layer of which is based upon a cleaned III-V material.

21. The method according to claim 1, wherein the microelectronic component is a light-emitting diode.
